(19) United States
(12) Patent Application Publication
(10) Pub. No.: US 2022/0093831 A1
(43) Pub. Date: Mar. 24, 2022

(54) CONVERSION PARTICLE, CONVERSION ELEMENT, OPTOELECTRONIC DEVICE, AND PROCESS FOR PRODUCING A CONVERSION PARTICLE

(71) Applicant: OSRAM Opto Semiconductors GmbH, Regensburg (DE)

(72) Inventors: Jens EBERHARD, Lemgo (DE); Andreas HANISCH, Regensburg (DE)

(21) Appl. No.: 17/424,719

(22) PCT Filed: Mar. 12, 2020
(86) PCT No.: PCT/EP2020/056672

§ 371 Date: Jul. 21, 2021

(30) Foreign Application Priority Data
Mar. 25, 2019 (DE) 10 2019 107 590.4

(51) Int. Cl. H01L 33/50; C09K 11/02; H01L 33/00; C09K 11/70

(52) U.S. Cl. CPC H01L 33/504; C09K 11/025; H01L 2933/0041; C09K 11/70; H01L 33/005

(57) ABSTRACT

A conversion particle is specified comprising a core formed with a phosphor, a shell formed with a polysiloxane, wherein the shell has a layer thickness of between at least 1 micrometer and at most 15 micrometers. Furthermore, a conversion element and an optoelectronic component comprising such a conversion particle are specified. In addition, a method for producing a conversion particle is specified.

A conversion particle, a conversion element, and an optoelectronic device are specified. In addition, a process for producing a conversion particle is specified.

A problem to be solved is to disclose an improved conversion particle, an improved conversion element and an improved optoelectronic device. A further problem to be solved is to specify a process by which the conversion particle can be passivated.

A conversion particle is specified. The conversion particle is configured to convert electromagnetic primary radiation of a first wavelength range into electromagnetic secondary radiation of a second wavelength range. In particular, the conversion particle is a particle comprising at least one type of phosphor.

According to at least one embodiment, the conversion particle comprises a core formed with a phosphor. For example, the core consists of a phosphor. The phosphor preferably comprises a crystalline, for example ceramic, host lattice, an organic conversion material, and/or quantum dots. Quantum dots are a nanoscopic material structure, for example fabricated with semiconductor materials.

According to at least one further embodiment, the conversion particle comprises a shell formed with a polysiloxane. The shell serves, among other things, to protect the core from external mechanical or chemical influences. By means of the shell, the core is protected by a denser network from possibly harmful environmental influences such as moisture. Polysiloxanes are chemical synthetic polymers in which silicon atoms are crosslinked via oxygen atoms. Molecular chains and/or molecular networks can preferably be formed. The additional free valence electrons of the silicon are saturated by further residues. A typical configuration in a polysiloxane consists to a large extent of two oxygen atoms and two radicals. Furthermore, the silicon atom can be crosslinked with further silicon atoms via three oxygen atoms.

According to at least one embodiment, the shell comprises a layer thickness between at least 1 micrometer and at most 15 micrometers. Preferably, the layer thickness of the shell is between 5 micrometers and 10 micrometers. The shell of the core is preferably dependent on a diameter of the core. The smaller the diameter of the core, the smaller the layer thickness of the shell. Accordingly, if the diameter of the core is large, the layer thickness of the shell is also larger. For example, with a large core, the shell can be thinner than the core.

In particular, the shell is transparent and permeable to primary and secondary electromagnetic radiation. In addition, the shell enables improved dispersibility into a polymer-based potting material.

According to at least one embodiment, the conversion particle comprises a core which is formed with a phosphor and a shell which is formed with a polysiloxane, wherein the shell comprises a layer thickness between at least 1 micrometer and at most 15 micrometers.

One idea of the present conversion particle is to surround the core with a thermally stable shell. By means of the shell, the core is better protected by a denser network, from any harmful environmental influences such as moisture, than a comparable core which is not surrounded by a shell.

Furthermore, the conversion particle is thus better embedded in other potting materials.

In addition, the more thermally stable shell around the core leads to prevention of cracking at and around the surface of the cores. The cracking is a major contributor to the observed optical aging of an optoelectronic device.

According to at least one embodiment, the polysiloxane comprises a T-unit. In particular, the T-unit has the following structure:

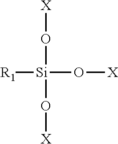

The residue R₁ is selected from a group consisting of substituted and unsubstituted alkyl, substituted and unsubstituted aryl, substituted and unsubstituted alkenyl, substituted and unsubstituted heteroatoms, and combinations thereof. X denotes a repeating unit. Preferably, the T-unit does not contain a reactive group for hydrosilylation.

According to at least one embodiment, the polysiloxane comprises a D-unit. In particular, the D-unit comprises the following structure:

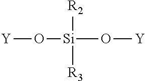

The residues R₂ and R₃ are independently selected from a group consisting of substituted and unsubstituted alkyl, substituted and unsubstituted aryl, substituted and unsubstituted alkenyl, substituted and unsubstituted heteroatoms, and combinations thereof. Y denotes a repeating unit.

According to at least one embodiment, the polysiloxane comprises a T-unit and a D-unit. The T-unit preferably comprises the following structure:

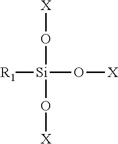

The D-unit preferably comprises the following structure:

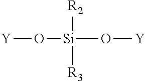

The residues R₁, R₂, and R₃ are independently selected from a group consisting of substituted and unsubstituted alkyl, substituted and unsubstituted aryl, substituted and unsubstituted alkenyl, substituted and unsubstituted heteroatoms, and combinations thereof. Preferably, the T-unit does not contain a reactive group for hydrosilylation.

As used herein, the D-unit and the T-unit refer to the relative number of oxygen and preferably carbon atoms attached to each silicon atom of the polysiloxane. In the present case, T-unit means that three oxygen atoms are bonded to the silicon atom. Thus, crosslinking to three further silicon atoms occurs there. Furthermore, the T units thus have a reduced proportion of organic groups. The D-unit denotes a silicon atom that has two oxygen atoms bonded to it. If only D units are bonded to each other, a polysiloxane chain is preferably obtained.

X and Y is a repeating unit in the present case. That is, at the positions where an X or a Y occurs, another silicon atom, with one or two radicals and one or two oxygen atoms, respectively, can be bonded. In addition, X and Y can be understood as end groups. The end group occurs when enough units are bonded together. When X and/or Y is an end group, X, Y is independently selected from a group consisting of substituted and unsubstituted alkyl, substituted and unsubstituted alkoxy, substituted and unsubstituted vinyl, hydroxyl, substituted and unsubstituted carboxylic acids, substituted and unsubstituted ester, H, substituted and unsubstituted aryl, and combinations thereof.

For example, in the structure below, a T-unit is shown with three other T-units:

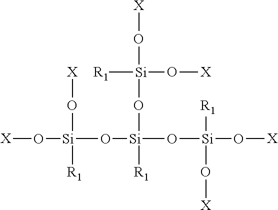

Since there is a single bond between the silicon atom and the oxygen atom, each unit is free to rotate in the present case. This structure is an example of a strongly crosslinked polysiloxane.

In another example, a D-unit is shown wherein a T-unit is located at the left Y and another D-unit at the right Y:

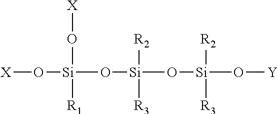

Preferably, a methyl group and/or a phenyl group are chosen here as R₁, R₂ and R₃:

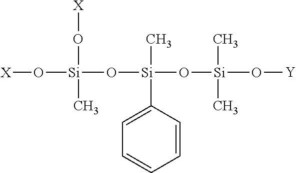

If only D units are aligned, a linear polysiloxane, a polysiloxane chain with few crosslinking sites, is obtained.

According to at least one embodiment, more than 30% of all units of the polysiloxane are T units. That is, for a chain length of the polysiloxane of, for example, 50 units, more than 15 units are T units and the other units are preferably D units. In particular, between at least 30% and at most 60% of the total units of the polysiloxane are T units. Thus, it is possible that the polysiloxane comprises a particularly small amount of organic material and therefore has only a small number of C-based crosslinks, for example C—C crosslinks. These C—C crosslinks, which are formed by hydrosilylation reactions, for example, would result in a thermally labile shell. Due to the increased number of T units, the polysiloxane has more thermally stable crosslinks, for example Si—O—Si crosslinks. These lead to a particularly thermally stable polysiloxane. This thermal stability can result in long-term temperature stability even at temperatures above 200° C. The polysiloxane of the shell is, for example, a thermoset elastomer.

According to at least one embodiment, a reactant of the polysiloxane comprises D units with an average molecular weight greater than 5000 Da with the general structure described above. Preferably, the average molecular weight is greater than 10000 Da. Y, the repeating unit, is presently between at least 55 and at most 200 for the reactant of the polysiloxane, which represents a long reactant chain. From the reactant of the polysiloxane with predominantly D units, a polysiloxane is produced in a curing reaction or crosslinking reaction, which, due to the long reactant chains, has few thermally labile crosslinks, for example C—C crosslinks. Thus, the polysiloxane is composed of several reactants of the polysiloxane by crosslinking. The proportion of crosslinks additionally formed during the curing reaction is relatively small in this case, and a thermoset polysiloxane, which is the material of the shell, is obtained. In addition to D units, the polysiloxane can also have other units, for example T units. Preferably, the residues R₂ and R₃ are methyl groups and/or phenyl groups. A difference between the reactant of the polysiloxane and the polysiloxane obtained after curing lies in the number of repeating units, that is, in the molecular weight. In particular, the reactant of the polysiloxane has shorter chains and thus a lower molecular weight than the corresponding polysiloxane.

Compared to conventional polysiloxanes with predominantly D units, the polysiloxane of the shell described herein has a lower number of C-based crosslinks, which would lead to a thermally labile shell. For example, the crosslinks are C—C crosslinks obtained by a hydrosilylation reaction.

According to at least one embodiment, the core is completely surrounded by the shell. That is, the core is completely surrounded and there is no free area on the core that is not covered by the shell. In this case, the core is preferably in direct contact with the shell.

According to at least one embodiment, the layer thickness of the shell is non-uniform. The average layer thickness here is, for example, between at least 1 micrometer and at most 15 micrometers. By non-uniform, it may be understood hereinafter that the shell is formed thinner at one location of the core than at another location of the core. The thinnest point of the layer thickness is preferably not thinner than 1 micrometer. The thickest point of the layer thickness of the shell is preferably not thicker than 15 micrometers. If the shell is formed too thin, then the thermal stability of the conversion particle is not guaranteed and if the shell is formed too thick, the processing of the shell poses a problem.

According to at least one embodiment, the conversion particle comprises exactly one core. For example, the conversion particle consists of exactly one core and the shell surrounding the core.

According to at least one embodiment, the core comprises a ceramic phosphor. The ceramic phosphor is preferably selected from a group consisting of garnet phosphors and nitride phosphors. A garnet phosphor comprises a crystalline host lattice in which the lattice sites are occupied by various elements.

For example, the garnet phosphor may be one of the following phosphors: YAG phosphor and/or LuAG phosphor. The YAG phosphor comprises the chemical formula Y₃Al₅O₁₂:Ce³⁺ and the LuAG phosphor has the chemical formula Lu₃Al₅O₁₂:Ce³⁺.

The group of nitride phosphors includes, for example, a SCASN phosphor with the chemical formula (Ca,Sr)AlSiN₃:Eu²⁺.

Other possible materials for the core include, in particular, the following aluminum-containing and/or silicon-containing phosphors:

(RE₁₋ₓCeₓ)₃(Al_{1-y}A′_{y})₅O₁₂ with 0<x<0.1 and 0≤y≤1,

(RE₁₋ₓCeₓ)₃(Al_{5-2y}Mg_{y}Si_{y})O₁₂ with 0<x≤0.1 and 0≤y≤2,

(RE₁₋ₓCeₓ)₃Al_{5-y}Si_{y}O_{12-y}N_{y} with 0<x≤0.1 and 0≤y≤0.5,

(RE₁₋ₓCeₓ)₂CaMg₂Si₃O₁₂:Ce³⁺ with 0<x≤0.1,

(AE₁₋ₓEUₓ)₂Si₅N₈ with 0<x≤0.1,

(AE₁₋ₓEuₓ)AlSiN₃ with 0<x≤0.1,

(AE₁₋ₓEuₓ)₂Al₂Si₂N₆ with 0<x≤0.1,

(Sr₁₋ₓEuₓ)LiAl₃N₄ with 0<x≤0.1,

(AE₁₋ₓEuₓ)₃Ga₃N₅ with 0<x≤0.1,

(AE₁₋ₓEuₓ)Si₂O₂N₂ with 0<x≤0.1,

(AEₓEu_{y})Si_{12-2x-3y}Al_{2x+3y}O_{y}N_{16-y} with 0.2≤x≤2.2 and 0<y≤0.1,

(AE₁₋ₓEuₓ)₂SiO₄ with 0<x≤0.1,

(AE₁₋ₓEuₓ)₃Si₂O₅ with 0<x≤0.1,

K₂(Si_{1-x-y}Ti_{y}Mnₓ)F₆ with 0<x≤0.2 and 0<y≤1−x,

(AE₁₋ₓEuₓ)₅(PO₄)₃Cl with 0<x≤0.2,

(AE₁₋ₓEuₓ)Al₁₀O₁₇ with 0<x≤0.2,

(Y_{1-x-y}GdₓCe_{y})₃Al₅O₁₂ mit 0≤x≤0.2 and 0<y≤0.05, and combinations thereof, wherein RE is one or more of Y, Lu, Tb, and Gd, AE is one or more of Mg, Ca, Sr, Ba, A′ is one or more of Sc and Ga, wherein the phosphor of the core may optionally include one or more halogens. The core is capable of absorbing in the near UV to blue region of the electromagnetic spectrum and emitting in the visible region of the electromagnetic spectrum.

According to at least one embodiment, the core comprises a d50 value between at least 0.5 micrometers and at most 30 micrometers. The d50 value is the volume-based average diameter of the core. For example, if the core has a d50 value of 0.5 micrometers, the shell may have a layer thickness between at least 200% and at most 250% of the d50 value of the core. For example, with a d50 value of the core of 30 micrometers, the shell may have a layer thickness of between at least 12% and at most 50% of the d50 value of the core. The layer thickness of the shell can thus be dependent on the d50 value of the core. Preferably, the layer thickness of the shell is between at least 12% and at most 250% of the d50 value of the core. Particularly preferably, the layer thickness is large relative to the core for smaller diameters of the core and the layer thickness is relatively small for large diameters of the core.

A conversion element is further specified. The conversion element is provided, for example, for converting a primary electromagnetic radiation of a first wavelength range into secondary electromagnetic radiation of a second wavelength range. For this purpose, for example, a plurality of the conversion particles is embedded in the conversion element. In particular, the conversion element may be formed as a conversion layer.

According to at least one embodiment, the conversion element comprises a plurality of conversion particles described herein. For example, the conversion particles may be formed identically or differently. For example, the plurality of conversion particles may differ in their core and/or shell. For example, a conversion particle with the same phosphor but with different shells in the core may be used. Further, a mixture of different conversion particles with the same polysiloxane in the shell and different phosphors in the core may be used. In addition, the conversion particles may have different shapes. For example, the conversion particle may be round and/or angular in shape. That is, all features disclosed for the conversion particles are also disclosed for the conversion element, and vice versa.

According to at least one embodiment, the conversion element comprises a potting material. The potting material is preferably transparent or translucent to primary electromagnetic radiation and secondary electromagnetic radiation.

According to at least one embodiment, the conversion particles are embedded in the potting material. That is, the conversion particle is preferably completely surrounded by the potting material. Due to the shell, the conversion particle exhibits particularly good or improved dispersibility in the potting material, which improves, for example, the color orthomogeneity of the component.

Furthermore, the potting material serves as additional protection against external mechanical or chemical influences.

According to at least one embodiment, the potting material differs from the material of the shell of the conversion particles. For example, the potting material and the material of the shell of the conversion particles both have polysiloxanes, but they differ in the chain length as well as in crosslinking units and residues as well as in possible processing steps.

According to at least one embodiment, the potting material is based on a reactant of the polysiloxane with predominantly D units with an average molecular weight of less than 5000 Da of the general structure:

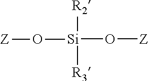

The residues R_{2′} and R_{3′} are independently selected from a group consisting of substituted and unsubstituted alkyl, substituted and unsubstituted alkoxy, substituted and unsubstituted aryl, substituted and unsubstituted aryloxy, substituted and unsubstituted alkenyl, substituted and unsubstituted heteroatoms, and combinations thereof. Additionally, Z of the reactant of the polysiloxane is a repeating unit, which is preferably between at least five and at most 50. Particularly preferably, between at least five and at most 25 units are linked together. The number of repeating units Z of the reactant of the polysiloxane for the potting material is preferably smaller than the number of repeating units Y of the reactant of the polysiloxane for the shell of the conversion particle. Z may further be an end group. Possible end groups are described for the repeating units X and Y. Preferably, Z is a reactive group, for example a C═C group and/or a SiH group, suitable for hydrosilylation. Particularly preferably, the average molecular weight of the reactant of the polysiloxane of the potting material is between 500 Da and 1000 Da. The reactant chains are cured in a crosslinking reaction to form the potting material. Compared to the polysiloxane of the shell, the potting material exhibits a plurality of thermally labile crosslinks, for example C—C crosslinks. In addition to D units, the potting material has, for example, a small proportion of crosslinking units in the form of, for example, T units. The small proportion of T units is, for example, at most 5% of all units. In the present case, the potting material is a thermoset.

If the potting material is compared with the polysiloxane of the shell, which has more than 30% of the total units implemented as T units, the thermally stable crosslinking, for example T units, of the potting material is comparatively low. Furthermore, the polysiloxane of the shell advantageously contains a small number of thermally labile C—C crosslinks.

In one embodiment, the reactant of the polysiloxane used as the potting material differs from the reactant of the polysiloxane used as the shell in that the average molecular weight is less than 5000 Da. After the reactant of the polysiloxane is cured, the potting material differs from the shell of the conversion particle in that the number of C—C crosslinks is significantly greater in the potting material. This results in a more thermally labile material.

The use of a potting material made from the reactant of the polysiloxane with D units with an average molecular weight greater than 5000 Da and/or the use of potting material with polysiloxanes with more than 30% of the total units T units, would be advantageous due to the good thermal stability. However, the reactant of the polysiloxane with D units with an average molecular weight greater than 5000 Da and/or the polysiloxanes with more than 30% of the total units T units cannot be used as potting material in conversion elements at present due to lengthy physicochemical curing methods as well as volatile substances and an uncontrollable pot life. In addition, due to the curing methods, these polysiloxanes can currently usually only be processed in thin layers, less than 100 micrometers, and thus cannot be used as potting material in optical components, for example. These disadvantages are overcome by using them as a shell in the conversion particle and are thus used here. The use of the reactant of the polysiloxane having D units with an average molecular weight greater than 5000 Da and/or the polysiloxanes having more than 30% of the total units T units as a shell and the use of the reactant of the polysiloxane having D units with an average molecular weight less than 5000 Da as a potting material leads to an optimal synergy.

An optoelectronic device is further specified. For example, the optoelectronic device is provided for generating and then emitting a primary electromagnetic radiation of a first wavelength range in a semiconductor chip. The emitted primary electromagnetic radiation is converted into secondary electromagnetic radiation in a conversion element comprising a plurality of conversion particles as described herein.

According to at least one embodiment, the optoelectronic device comprises a conversion element described herein. That is, all features disclosed for the conversion element are also disclosed for the optoelectronic device, and vice versa.

According to at least one embodiment, the optoelectronic device comprises a semiconductor chip that emits primary electromagnetic radiation of a first wavelength range during operation. The semiconductor chip is, for example, a light emitting diode chip or a laser chip. In operation, the semiconductor chip may emit electromagnetic primary radiation from the wavelength range of UV radiation and/or blue light, for example.

According to at least one embodiment, the optoelectronic device comprises a conversion element described herein that is arranged to emit secondary radiation of a second wavelength range. The second wavelength range is preferably different from the first wavelength range. The conversion element is preferably arranged downstream of the semiconductor chip. Preferably, the conversion element is directly applied to the semiconductor chip. Furthermore, the conversion element may be applied to the semiconductor chip with an adhesive layer. The conversion element is configured to generate a partial conversion or a full conversion of the electromagnetic primary radiation. This depends in particular on the phosphors used and the thickness of the conversion element. Downstream means that at least 50%, in particular at least 85% of the radiation emitted by the semiconductor chip enters the conversion element.

According to at least one embodiment, the conversion element comprises a thickness of greater than 100 micrometers.

Compared to conventional optoelectronic devices having a conversion element with conversion particles without a present shell, the present optoelectronic devices exhibit a lower delamination phenomenon in the periphery of the core as well as cracking in the potting material. This results in a slower optical aging of the optoelectronic device and a shifting of the color locus is minimized. The potting material has fewer microcracks and the core of the conversion particle is thus protected against environmental influences such as moisture. One reason for this is that the core is better protected by means of the shell through a denser network, due to an increased proportion of oxygen-bridged cross-links or less thermally labile cross-links, than a comparable core that is not surrounded by a shell.

Furthermore, by suitable choice of the residues R advantages in the optical properties can be achieved by adjustable refractive indices of the shell to the surrounding potting material.

A process for producing a conversion particle is further specified. Preferably, the process described herein can be used to produce the conversion particle described herein. That is, all features disclosed for the conversion particle are also disclosed for the process for producing a conversion particle, and vice versa.

According to at least one embodiment of the process for producing a conversion particle, a mixture comprising cores and a reactant of the polysiloxane is provided. The cores are coated with the reactant of the polysiloxane. The coated cores are then singulated and the reactant of the polysiloxane coating the core is cured.

The reactant of the polysiloxane can preferably be selected from the group of polysiloxane reactants and/or polysilazane reactants:

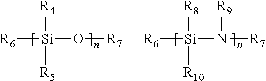

Here, the residues R₄ and Rs are—independently from each other—selected from a group consisting of substituted and unsubstituted alkyl, substituted and unsubstituted alkoxy, substituted and unsubstituted aryl, substituted and unsubstituted aryloxy, substituted and unsubstituted alkenyl, substituted and unsubstituted heteroatoms, and combinations thereof,

the residues R₈, R₉ and R₁₀ are—independently from each other—selected from a group consisting of H, substituted and unsubstituted alkyl, substituted and unsubstituted alkoxy, substituted and unsubstituted aryl, substituted and unsubstituted aryloxy, substituted and unsubstituted alkenyl, substituted and unsubstituted heteroatoms, and combinations thereof; and

the residues R₆ and R₇ are—independently from each other—selected from a group consisting of substituted and unsubstituted alkoxy, substituted and unsubstituted vinyl, hydroxyl, substituted and unsubstituted carboxylic acid, substituted and unsubstituted ester, H, and combinations thereof. The reactants of the polysiloxane preferably have hydrolyzable functional groups, such as alkoxy and/or ester groups, and/or are partially hydrolyzed. n is a repeating unit and may correspond to X, Y and Z herein.

In other words, the reactant of the polysiloxane comprises a substituted polysiloxane reactant or a substituted polysilazane reactant. The backbone of the polysiloxane reactant comprises alternating silicon and oxygen atoms, the backbone of the polysilazane reactant comprises alternating silicon and nitrogen atoms. Typically, the precursor is a liquid at room temperature if it is a polysiloxane. In some cases, a small amount of solvent is required for the polysilazane reactant to be in liquid form. The three-dimensional polysiloxane is formed from the liquid or solution-based reactant using reactive groups on the silicon atoms.

A further embodiment of the reactant of the polysiloxane is described in the description above as D and T units.

For the production of the polysiloxane in which more than 30% of all units are T units, a mixture of the reactant of the polysiloxane having a selected ratio of T units and D units is required. In this case, the proportion of more than 30% T units may result from the crosslinking reaction. Further, the reactant of the polysiloxane that reacts to form the polysiloxane having more than 30% of the total units T units preferably does not comprise reactive groups suitable for hydrosilylation. The reactant of the polysiloxane in this case preferably has between five and 50 repeating units, particularly preferably between five and 25 repeating units, and is thus already a polymer.

The reactant of the polysiloxane, which has D units with an average molecular weight greater than 5000 Da, preferably comprises reactive groups suitable for hydrosilylation and/or condensation reaction. In some cases, a small amount of solvent is required to obtain a processable formulation from the reactant of the polysiloxane with greater than 5000 Da. After curing, the material is a highly crosslinked network consisting mainly of siloxane bonds, Si—O—Si crosslinks.

The coating of the cores is done by introducing the cores into the reactant of the polysiloxane. Here, the cores are preferably directly and completely coated by the reactant of the polysiloxane. In this step, the cores are surrounded by the reactant of the polysiloxane in a continuous layer. That is, the cores are surrounded by the reactant of the polysiloxane. Although the cores are dispersed in this case, they are continuously embedded.

In a next step, the coated cores are singulated. Preferably, each coated core is singulated. By this is meant that each core comprises exactly one shell based on the reactant of the polysiloxane. The singulation is carried out in particular by means of a spraying process.

Preferably, the reactant of the polysiloxane is first cured at the surface and then completely cured to form the shell. Preferably, surface curing occurs when the coated cores are singulated.

According to at least one embodiment of the process, the singulation of the coated cores is performed by means of a spraying process. The spraying process results in the coated cores being singulated and thus each coated core is partially cured completely or on the surface of the shell. Particularly preferably, the singulation by means of the spraying process leads to a reduction or prevention of agglomeration, since the singulation cures the surface of the shell and consequently the coated cores, which correspond to the conversion particles when fully cured, do not aggregate.

According to at least one embodiment of the process, the curing of the reactant of the polysiloxane around the core is performed by at least one of the following processes: use of a hydrolysis accelerator, use of catalysts, change of pH value, change of ion concentration, change of temperature, use of a solvent, irradiation with electromagnetic waves.

For example, the coated cores are sprayed into an inert solvent that promotes the curing of the reactant of the polysiloxanes only superficially. Further, the superficially curing of the reactant of the polysiloxane coating the core can take place in a heated drying tower. Another example is the introduction of the coated cores by means of a spraying process into a climatic chamber/room/tower, which may promote the curing of the reactant of the polysiloxane only superficially. The superficial curing of the reactant of the polysiloxane coating the core is likewise favored by a spraying process with beam guidance along an electromagnetic irradiation path. Preferably, these processes can be combined. If the reactant of the polysiloxane is not fully cured to the polysiloxane, another physical or chemical process is used to fully cure it. For example, the coated core is thermally cured to complete crosslinking. This is done, for example, in a drying oven. After the reactant of the polysiloxane is cured, the conversion particle is obtained.

A further process for producing a conversion particle described herein is disclosed.

According to at least one embodiment of the process for producing a conversion particle described herein, a mixture comprising cores and a reactant of the polysiloxane is provided. At the beginning of the process, a layer is formed from the reactant of the polysiloxane and the core, wherein the thickness of the layer is preferably less than 100 micrometers. Subsequently, the reactant of the polysiloxane is cured to form the shell. This is done, for example, as described above using chemical and physical processes. In a next step, the layer is preferably ground and/or broken up so that exactly one core with a shell is obtained. Within such a grinding process or break-up process, the shell of the core preferably remains intact to a greater extent than 90%, in relation to the shell before the grinding process or break-up process.

To form a conversion element, the produced conversion particles are embedded in the potting material of the conversion element.

One idea of the present conversion particle is to achieve an improved adhesion to the potting material by intrinsic compatibility of the material classes and interfaces. Furthermore, already known processes for improving adhesion can be applied to the conversion particle. These include, but are not limited to, powder plasma processes.

In addition, the shell around the core leads to a prevention of cracking at and around the surface of the cores. The cracking is a major contributor to the observed optical aging of an optoelectronic device. On the one hand, there is an increasing shift in the color locus due to both the scattering effect of micro-cracks in the potting material and the now simplified degradation of the phosphors due to environmental influences such as moisture; on the other hand, the deheating of the cores is reduced by the described aging effects, and further accelerating embrittlement, cracking and delamination. Yellowing of the potting material due to the Stokes heating of the core is likewise reduced or even avoided, since the distance between the potting material and core is increased and the surface is increased by the shell.

Another advantage is that the refractive index between the shell and the potting material can be adjusted, resulting in improved optical properties.

Further advantageous embodiments and further embodiments of the conversion particle, conversion element and optoelectronic device and of the process for producing a conversion particle are apparent from the exemplary embodiments described below in connection with the figures.

It shows:

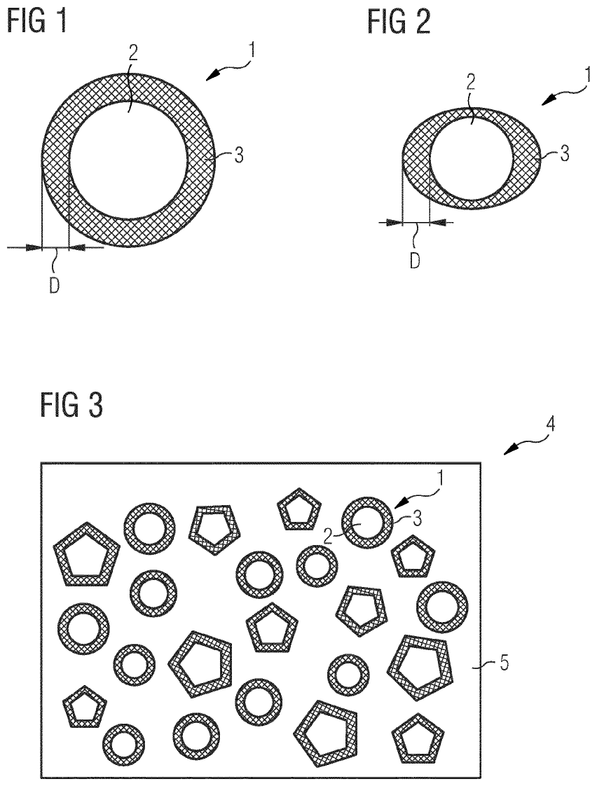

FIGS. 1 and 2, respectively, a schematic sectional view of a conversion particle according to an exemplary embodiment, respectively,

FIG. 3 a schematic sectional view of a conversion element according to an exemplary embodiment,

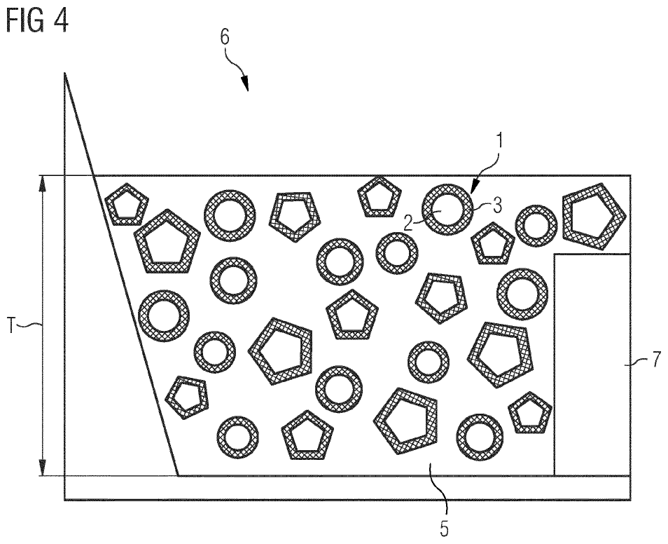

FIG. 4 a section of a schematic sectional view of an optoelectronic device according to an exemplary embodiment,

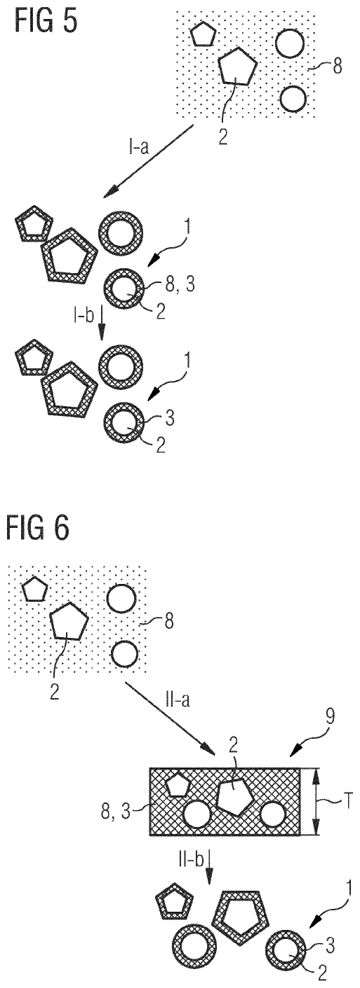

FIGS. 5 and 6 schematic sectional views of different process stages of a process for producing a conversion particle according to a respective exemplary embodiment.

Identical, similar or similar-acting elements are given the same reference signs in the figures. The figures and the proportions of the elements shown in the figures with respect to one another are not to be regarded as to scale. Rather, individual elements, in particular layer thicknesses, may be shown exaggeratedly large for better representability and/or understanding.

The conversion particle 1 according to the exemplary embodiment of FIG. 1 comprises a core 2 and a shell 3. The core 2 is formed with a phosphor and the shell 3 is formed with a polysiloxane. The phosphor is preferably a ceramic phosphor. Further, the core 2 has a d50 value of between at least 0.5 micrometers and at most 30 micrometers. The shell 3 has a layer thickness D of between at least 1 micrometer and at most 15 micrometers. For example, if the core has a d50 value of 0.5 micrometers, the shell may have a layer thickness of up to 250% of the d50 value of the core. For example, if the core has a d50 value of 30 micrometers, the shell can have a layer thickness of 30% of the d50 value of the core. The polysiloxane of the shell 3 comprises T units and D units. The T-unit comprises the following structure:

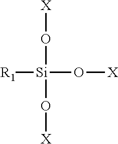

The D-unit comprises the following structure:

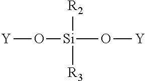

The residues R₁, R₂, and R₃ are independently selected from a group consisting of substituted and unsubstituted alkyl, substituted and unsubstituted aryl, substituted and unsubstituted alkenyl, substituted and unsubstituted heteroatoms, and combinations thereof. Preferably, the residues R₁, R₂ and R₃ comprise a methyl group and/or a phenyl group. X and Y show a repeating unit, that is, at position X and Y, respectively, there is bonded another silicon atom, with oxygen atoms or residues, respectively. More than 30% of the total units of the polysiloxane are T units, this leads to a strong crosslinking of the polysiloxane, preferably Si—O—Si crosslinks obtained by condensation reactions, resulting in a dense, thermally stable polysiloxane with a small amount of organic material. A reactant of the polysiloxane may already be a polymer that has shorter chains than the polysiloxane and does not have such a strong crosslinking. The cured polysiloxane is composed of several reactants of the polysiloxane. The reactant of the polysiloxane of the shell preferably has between five and 50 repeating units, particularly preferably between five and 25 repeating units.

Furthermore, the shell 3 may be formed from a polysiloxane which preferably comprises D units. Here, between at least 55 and at most 200 repeating units Y of the D unit form the reactant of the polysiloxane. The average molecular weight of the educt of the polysiloxane is here greater than 5000 Da, preferably greater than 10000 Da. The polysiloxane obtained after a curing reaction or crosslinking reaction has a low number of thermally labile crosslinks formed by hydrosilylation reactions due to the high molecular weight reactant of the polysiloxane.

Thus, the polysiloxane may be a polysiloxane in which at least 30% of the total units are T units, and/or a polysiloxane having as reactant D units with an average molecular weight greater than 5000 Da. The formation of a shell 3 around the core 2 leads to a denser network around the cores 2, which better protects the core 2 against harmful environmental influences such as moisture. Furthermore, crack formation around the core 2 is thus reduced. The crack formation contributes significantly to the observed optical aging. In addition, the core 2 is completely surrounded by the shell 3. Furthermore, the shell 3 is thermally stable and thus conducts heat away from the core 2 and thus provides improved cooling of the conversion particle 1 due to the increased surface.

The conversion particle 1 according to the exemplary embodiment of FIG. 2 shows a layer thickness D of the shell 3, which is formed non-uniformly around the core 2. The average layer thickness D here is preferably between 1 micrometer and 15 micrometers. In the present case, the shell 3 is formed thinner at one point of the core 2 than at another point of the core 2.

The exemplary embodiment shown in FIG. 3 has a conversion element 4 with a plurality of conversion particles 1. For example, the conversion particles may be formed identically or differently. For example, the plurality of conversion particles may differ in their core and/or shell. Furthermore, the conversion particles may have different shapes. For example, the conversion particle may be round and/or angular in shape. The conversion particles 1 are embedded in a potting material 5, wherein the potting material 5 is different from the material of the shell 3 of the conversion particles 1. The reactant of the potting material 5 is based on a polysiloxane with D units having an average molecular weight of less than 5000 Da, having the general structure:

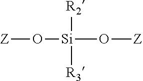

The residues R_{2′} and R_{3′} as well as the repeating unit Z are described above. The number of repeating unit Z, based on the reactant of the polysiloxane of the potting material, is smaller than the number of repeating unit Y, based on the reactant of the polysiloxane of the shell. The potting material 5 is formed transparent or translucent to primary electromagnetic radiation and secondary electromagnetic radiation. The cores 2 are spaced apart from each other by their shell 3. The shell 3 of the cores 2 should not be too thin and not too thick. The potting material 5 has a larger number of thermally labile cross-links, for example C—C cross-links, which are predominantly produced by hydrosilylation reactions, compared to the shell 3. The potting material 5 serves to provide additional protection against external mechanical or chemical influences.

The exemplary embodiment of FIG. 4 shows a section of an optoelectronic device 6 with a semiconductor chip 7, which in operation emits electromagnetic primary radiation of a first wavelength range, and the conversion element 4, which is arranged to emit electromagnetic secondary radiation of a second wavelength range. The conversion element 4 is arranged downstream of the semiconductor chip 7. The conversion element 4 has a thickness T of greater than 100 micrometers. The shell 3 leads to a reduced cracking of the potting material 5, which minimizes the optical aging of the optoelectronic device 6. Thus, there is a reduced shift of the color locus since the scattering effect of microcracks in the potting material 5 is minimized.

In the process for producing a conversion particle 1 according to the exemplary embodiment of FIG. 5, a mixture comprising cores 2 and an educt of polysiloxane 8 is provided in a first step. The cores 2 are coated with the reactant of the polysiloxane 8. The coated cores 2 are singulated in a next process step I-a and then the reactant of the polysiloxane 8 coating the core 2 is cured, process step I-b. The singulation of the coated cores 2 is carried out by means of a spraying process, in which the surface of the reactant of the polysiloxane 8 is first cured. The curing of the reactant of the polysiloxane 8 or the curing of the surface of the reactant of the polysiloxane 8 around the core 2 is carried out by at least one of the following processes: use of a hydrolysis accelerator, use of catalysts, change of pH value, change of ion concentration, change of temperature, use of a solvent, irradiation with electromagnetic waves. For example, the coated cores 2 are sprayed into a heated drying tower where the reactant of the polysiloxane 8 is cured at least superficially. Furthermore, the coated core 2 can be sprayed into a climatic chamber/room/tower, which likewise promotes spuerficial curing. Finally, the singulated coated cores 2 are fully cured by chemical or physical processes, for example in an oven, and the conversion particle 1 is obtained.

The exemplary embodiment of FIG. 6 shows a further process for producing a conversion particle 1. First, a mixture comprising cores 2 and a reactant of the polysiloxane 8 is provided. These are formed into a layer 9, II-a. The thickness T of the layer 9 is preferably less than 100 micrometers. Subsequently, the reactant of the polysiloxane 8 is cured to the polysiloxane of the shell 3. In a further process step II-b, the layer 9 is broken up and/or ground and the conversion particles 1 are obtained.

The conversion particles 1 thus obtained are then introduced into a potting material 5 to form the conversion element 4.

The features and exemplary embodiments described in connection with the figures may be combined with each other according to further exemplary embodiments, even though not all combinations are explicitly described. Furthermore, the exemplary embodiments described in connection with the figures may alternatively or additionally have further features according to the description in the general part.

The invention is not limited to the exemplary embodiments by the description based thereon. Rather, the invention encompasses any new feature as well as any combination of features, which in particular includes any combination of features in the patent claims, even if this feature or combination itself is not explicitly stated in the patent claims or exemplary embodiments.

This patent application claims priority to the German patent application 102019107590.4, the disclosure content of which is hereby incorporated by reference.

### REFERENCE SIGN

1 conversion particle

2 core

3 shell

4 conversion element

5 potting material

6 optoelectronic device

7 semiconductor chip

8 reactant of the polysiloxane

9 layer

D layer thickness

T thickness

I-a process step

I-b process step

II-a process step

II-b process step

1. A conversion particle comprising
a core which is formed with a phosphor
a shell which is formed with a polysiloxane, wherein
the shell comprises a layer thickness between at least 1 micrometer and at most 15 micrometers, and
the polysiloxane comprises a D-unit,
the D-unit comprises the following structure: 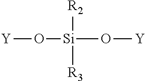
the residues R₂ and R₃ are independently of each other selected from a group consisting of substituted and unsubstituted alkyl, substituted and unsubstituted aryl, substituted and unsubstituted alkenyl, substituted and unsubstituted heteroatoms, and combinations thereof,
Y is a repeating unit.

2. The conversion particle according claim 1,
wherein
the polysiloxane comprises a T-unit in addition to the D-unit,
the T-unit comprises the following structure: 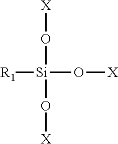
the D-unit comprises the following structure: 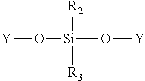
the residues R₁, R₂, and R₃ are independently of each other selected from a group consisting of substituted and unsubstituted alkyl, substituted and unsubstituted aryl, substituted and unsubstituted alkenyl, substituted and unsubstituted heteroatoms, and combinations thereof,
X and Y is a repeating unit.

3. The conversion particle according to claim 2,
wherein more than 30% of all units of the polysiloxane are T units.

4. The conversion particle according to claim 1,
wherein a reactant of the polysiloxane comprises D units with an average molecular weight greater than 5000 Da, and
wherein Y of the reactant of the polysiloxane is between at least 55 and at most 200.

5. The conversion particle according to claim 1,
wherein a reactant of the polysiloxane comprises D units with an average molecular weight greater than 10000 Da.

6. The conversion particle according to claim 1,
wherein the core is completely surrounded by the shell.

7. The conversion particle according to claim 1,
wherein the layer thickness of the shell is non-uniform.

8. The conversion particle according to claim 1,
wherein the conversion particle comprises in particular exactly one core.

9. The conversion particle according to claim 1,
wherein the core comprises a ceramic phosphor.

10. The conversion particle according to claim 1,
wherein the core comprises a d50 value of between at least 0.5 micrometers and at most 30 micrometers.

11. A conversion element with
a plurality of conversion particles according to claim 1, and
a potting material, wherein
the conversion particles are embedded in the potting material, and
the potting material is different from the polysiloxane of the shell of the conversion particles.

12. The conversion element according to claim 11,
wherein
the potting material is based on a reactant of the polysiloxane having D units of the following structure: 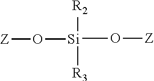
having an average molecular weight of less than 5000 Da, and
Z is a repeating unit between at least 5 and at most 50.

13. An optoelectronic device with
a semiconductor chip which, in operation, emits electromagnetic primary radiation of a first wavelength range, and
a conversion element according to claim 11, which is arranged to emit electromagnetic secondary radiation of a second wavelength range, wherein
the conversion element is arranged downstream of the semiconductor chip, and
in which the conversion element comprises a thickness of greater than 100 micrometers.

14. A process for producing a conversion particle comprising the steps:
A) providing a mixture comprising cores and an reactant of the polysiloxane, wherein the core is formed with a phosphor,
B) coating the cores with the reactant of the polysiloxane,
C) singulation of the coated cores, wherein the singulation of the coated cores can be performed by means of a spraying process,
D) curing the reactant of the polysiloxane which coats the core to form a shell, wherein the shell comprises a layer thickness of between at least 1 micrometer and at most 15 micrometers.

15. The process for producing a conversion particle according to claim 14,
wherein the singulation of the coated cores is performed by means of a spraying process.

16. The process for producing a conversion particle according to claim 14,
wherein the curing of the reactant of the polysiloxane around the core is performed by at least one of the following processes: use of a hydrolysis accelerator, use of catalysts, change of pH value, change of ion concentration, change of temperature, use of a solvent, irradiation with electromagnetic waves.

17. A process for producing a conversion particle according to claim 1 comprising the steps:
A) providing a mixture comprising cores and a reactant of the polysiloxane,
B) forming a layer from the reactant of the polysiloxane and the core, wherein the thickness of the layer is in particular less than 100 micrometers,
C) curing the reactant of the polysiloxane to form the shell,
D) breaking up and/or grinding the layer.
